(19) United States
(12) Patent Application Publication
(10) Pub. No.: US 2019/0371725 A1
(43) Pub. Date: Dec. 5, 2019

(54) ON-CHIP DIFFERENTIAL METAL-OXIDE-METAL/METAL-INSULATOR-METAL CAPACITOR WITH IMPROVED CIRCUIT ISOLATION

(71) Applicant: QUALCOMM Incorporated, San Diego, CA (US)

(72) Inventors: Haitao CHENG, San Diego, CA (US); Zhang JIN, San Diego, CA (US)

(21) Appl. No.: 15/996,234

(22) Filed: Jun. 1, 2018

(51) Int. Cl. H01L 23/522; H01L 23/528; H01L 49/02; H01L 23/66

(52) U.S. Cl. CPC H01L 23/5223; H01L 23/528; H01L 28/60; H04B 1/40; H01L 23/66; H01L 2223/6677; H01L 2223/6616; H01L 23/5226

(57) ABSTRACT

An integrated circuit with differential metal-oxide-metal (MOM)/metal-insulator-metal (MIM) capacitors to improve circuit isolation includes a first multi-layer capacitor in a first path of a differential circuit and a second multi-layer capacitor in a second path of the differential circuit. The first multi-layer capacitor resides in a first interconnect layer and a second interconnect layer and includes a first pair of ports. The second multi-layer capacitor overlaps one or more portions of the first multi-layer capacitor. The second multi-layer capacitor includes a second pair of ports and resides in a third interconnect layer and a fourth interconnect layer.

### BACKGROUND

### Field

Aspects of the present disclosure relate to semiconductor devices and, more particularly, to on-chip differential metal-oxide-metal (MOM)/metal-insulator-metal (MIM) capacitors with improved circuit isolation.

### Background

Mobile radio frequency (RF) chips (e.g., mobile RF transceivers) have migrated to a deep sub-micron process node due to cost and power consumption considerations. Designing mobile RF transceivers is further complicated by added circuit functions for supporting communication enhancements, such as carrier aggregation. Further design challenges for mobile RF transceivers include using passive devices, which directly affect analog/RF performance considerations, including mismatch, noise, and other performance considerations.

Analog integrated circuits use various types of passive devices, such as integrated capacitors. These integrated capacitors may include metal-oxide-semiconductor (MOS) capacitors, p-n junction capacitors, metal-insulator-metal (MIM) capacitors, poly-to-poly capacitors, metal-oxide-metal (MOM) capacitors, and other like capacitor structures. MOM capacitors are also known as vertical parallel plate (VPP) capacitors, natural vertical capacitors (NVCAP), lateral flux capacitors, comb capacitors, as well as interdigitated finger capacitors. MOM capacitors exhibit beneficial characteristics including high capacitance density, low parasitic capacitance, superior RF characteristics, and good matching characteristics without additional masks or process steps relative to other capacitor structures. MOM capacitor structures realize capacitance by using the fringing capacitance produced by sets of interdigitated fingers. For example, MOM capacitors harness lateral capacitive coupling between plates formed by metallization layers and wiring traces.

The design of mobile RF transceivers may include integrating MOM/MIM capacitors with inductors, transformers and other electronic devices. Unfortunately, certain capacitor configurations in the circuit degrade isolation within the circuit.

### SUMMARY

An integrated circuit may include a first multi-layer capacitor in a first path of a differential circuit. The first multi-layer capacitor includes a first pair of ports. The first multi-layer capacitor resides in a first interconnect layer and a second interconnect layer. The integrated circuit also includes a second multi-layer capacitor in a second path of the differential circuit. The second multi-layer capacitor overlaps one or more portions of the first multi-layer capacitor. The second multi-layer capacitor includes a second pair of ports and resides in a third interconnect layer and a fourth interconnect layer.

A method of fabricating an integrated circuit may include fabricating a first multi-layer capacitor in a first path of a differential circuit. The first multi-layer capacitor includes a first pair of ports. The first multi-layer capacitor resides in a first interconnect layer and a second interconnect layer. The method also includes fabricating a second multi-layer capacitor in a second path of the differential circuit. The second multi-layer capacitor overlaps one or more portions of the first multi-layer capacitor. The second multi-layer capacitor includes a second pair of ports and resides in a third interconnect layer and a fourth interconnect layer.

A radio frequency (RF) front end module includes an integrated circuit having a first multi-layer capacitor in a first path of a differential circuit. The first multi-layer capacitor includes a first pair of ports. The first multi-layer capacitor resides in a first interconnect layer and a second interconnect layer. The integrated circuit also includes a second multi-layer capacitor in a second path of the differential circuit. The second multi-layer capacitor overlaps one or more portions of the first multi-layer capacitor. The second multi-layer capacitor includes a second pair of ports and resides in a third interconnect layer and a fourth interconnect layer. The RF front end also has an antenna coupled to the integrated circuit.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 shows a block diagram of a wireless communication device.

FIG. 2 is a cross-section illustrating an integrated circuit (IC) device including an interconnect stack that contains conventional metal-oxide-metal (MOM) capacitor structures.

FIG. 3A is a schematic diagram illustrating a differential circuit including metal-oxide-metal (MOM) capacitors in different paths of the differential circuit and in different interconnect layers, according to aspects of the present disclosure.

FIGS. 3B and 3C illustrate cross-sections of portions of the metal-oxide-metal (MOM) capacitors of FIG. 3A.

FIG. 4A illustrates a top view of a first metal-oxide-metal (MOM) capacitor used in a first path of a differential circuit, according to aspects of the present disclosure.

FIG. 4B illustrates a top view of a second metal-oxide-metal (MOM) capacitor used in a second path of the differential circuit, according to aspects of the present disclosure.

FIG. 4C illustrates a top view of the first metal-oxide-metal (MOM) capacitor of FIG. 4A overlapped with the second metal-oxide-metal capacitor of FIG. 4B, according to aspects of the present disclosure.

FIG. 5 is a schematic diagram of metal-oxide-metal (MOM) capacitors for different paths of a differential circuit in different interconnect layers, according to aspects of the present disclosure.

FIG. 6A illustrates a top view of a first metal-oxide-metal (MOM) capacitor used in a first path of a differential circuit, according to aspects of the present disclosure.

FIG. 6B illustrates a top view of a second MOM capacitor having a different dimension than the first MOM capacitor of FIG. 6A and used in a second path of the differential circuit, according to aspects of the present disclosure.

FIG. 6C illustrates a capacitor structure including a top view of the first MOM capacitor of FIG. 6A overlapping a top view of the second MOM capacitor of FIG. 6B, according to aspects of the present disclosure.

FIG. 7A illustrates a top view of a first interconnect layer of a first metal-oxide-metal (MOM) capacitor used in a first path of a differential circuit, according to aspects of the present disclosure.

FIG. 7B illustrates a top view of a second interconnect layer of the first metal-oxide-metal (MOM) capacitor of FIG. 7A, according to aspects of the present disclosure.

FIG. 7C illustrates a cross-section of the first metal-oxide-metal (MOM) capacitor of FIG. 7A.

FIG. 8A and FIG. 8B illustrate a perspective view of a dual capacitor structure and a corresponding top view of the dual capacitor structure, according to aspects of the present disclosure.

FIG. 9A is a schematic diagram illustrating a differential circuit including metal-insulator-metal (MIM) capacitors in different paths of the differential circuit and in different interconnect layers, according to aspects of the present disclosure.

FIG. 9B is a schematic diagram illustrating a differential circuit including metal-insulator-metal (MIM) capacitors in different paths of the differential circuit and in different interconnect layers, according to aspects of the present disclosure.

FIG. 10 is a process flow diagram illustrating a method for fabricating an integrated circuit, according to an aspect of the present disclosure.

FIG. 11 is a block diagram showing an exemplary wireless communication system in which a configuration of the present disclosure may be advantageously employed.

FIG. 12 is a block diagram illustrating a design workstation used for circuit, layout, and logic design of a semiconductor component, according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR”, and the use of the term “or” is intended to represent an “exclusive OR”. As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Analog integrated circuits use various types of passive devices, such as integrated capacitors. These integrated capacitors may include metal-oxide-semiconductor (MOS) capacitors, p-n junction capacitors, metal-insulator-metal (MIM) capacitors, poly-to-poly capacitors, metal-oxide-metal (MOM) capacitors, and other like capacitor structures. A process flow for fabrication of the capacitors may include front-end-of-line (FEOL) processes, middle-of-line (MOL) processes, and back-end-of-line (BEOL) processes.

MOM capacitors are one of the most widely used capacitors due to their beneficial characteristics. In particular, MOM capacitors are used for providing high quality capacitors in semiconductor processes without incurring the cost of an extra processing step relative to other capacitor structures. MOM capacitor structures realize capacitance by using the fringing capacitance produced by sets of interdigitated fingers. That is, MOM capacitors harness lateral capacitive coupling between plates formed by metallization layers and wiring traces.

The design of radio frequency integrated circuits (e.g., radio frequency (RF) transceivers for user equipments) may include integrating MOM/MIM capacitors into a differential circuit. Some MOM/MIM capacitors in differential circuits are arranged in a side-by-side configuration. For example, the capacitors are arranged such that a first capacitor of a first path of the differential circuit is on a same back-end-of-line interconnect layer(s) as a second capacitor on a second path of the differential circuit. Unfortunately, integrating the first capacitor and the second capacitor in accordance with the side-by-side configuration results in poor isolation because of a large current loop. For example, a center-to-center distance between the first capacitor and the second capacitor on the same back-end-of-line interconnect layer(s) is large (e.g., thirty micrometers). An obvious downside to this side-by-side configuration of the capacitors in the differential circuit is space constraints. In addition, the degraded isolation defeats the purpose of the differential circuit, which is to improve isolation.

A differential circuit (or differential pair) may include two communication paths (e.g., two transmission lines) that have equal and opposite polarity signals. For example, alternating current (AC) coupling capacitors are inserted in series with each path of a differential circuit/pair to provide direct current (DC) isolation between two ends of the communication path. The communication paths that are connected to the AC coupling capacitors are located in internal layers (back-end-of-line interconnect layers) of an electronic device (e.g., printed circuit board). To couple or connect the terminals or ports of the capacitors to the communication paths, a via may be used at each end of the capacitors.

Various aspects of the present disclosure include an integrated circuit (e.g., a differential circuit) that includes a first multi-layer capacitor in a first path of the differential circuit and a second multi-layer capacitor in a second path of the differential circuit. The first multi-layer capacitor resides in a first interconnect layer and a second interconnect layer. The second multi-layer capacitor resides in a third interconnect layer and a fourth interconnect layer. The first, second, third, and fourth layers are all different interconnect layers. The first multi-layer capacitor includes a first pair of ports and the second multi-layer capacitor includes a second pair of ports. The second multi-layer capacitor overlaps the first multi-layer capacitor. The first multi-layer capacitor and the second multi-layer capacitor can be metal-oxide-metal (MOM) capacitors or a metal-insulator-metal (MIM) capacitors.

The differential circuit includes two independent communication paths (the first path and the second path) with each communication path terminating at a reference node (e.g., a load). For example, current flows into the first path at a first port of the first pair of ports, through the first multi-layer capacitor in a first set of back-end-of-line interconnect layers (e.g., the first interconnect layer and the second interconnect layer) and into the reference node from a second port of the first pair of ports. A different polarity current flows out of reference node.

According to aspects of the present disclosure, a current loop including the first and the second path is reduced relative to the current loop associated with a differential circuit where the capacitors are arranged in a side-by-side configuration. When all of the impedances along the first path are equal in magnitude to all of the impedances along the second path, the current flowing into the reference node and the current flowing out of the reference node are equal in magnitude and opposite in polarity such that the net current into and out of the reference node is zero.

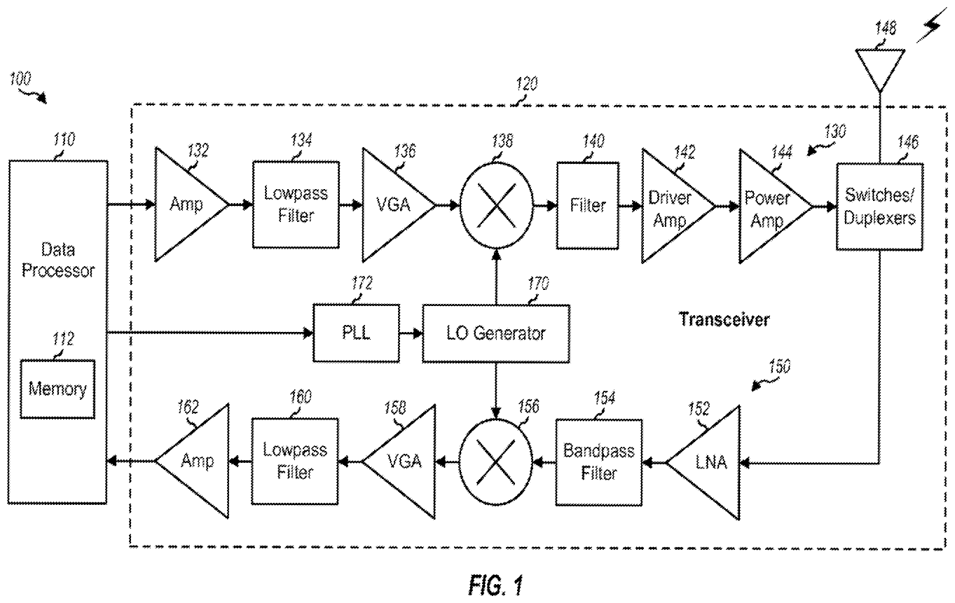

FIG. 1 shows a block diagram of an exemplary design of a wireless communication device or wireless communication device 100 that may include the capacitor circuit discussed herein. In this exemplary design, the wireless communication device 100 includes a data processor 110 and a transceiver 120. The transceiver 120 includes a transmitter 130 and a receiver 150 that support bi-directional wireless communication. In general, the wireless communication device 100 may include any number of transmitters and any number of receivers for any number of communication systems and any number of frequency bands.

In the transmit path, the data processor 110 processes data to be transmitted and provides an analog output signal to the transmitter 130. Within the transmitter 130, the analog output signal is amplified by an amplifier (Amp) 132, filtered by a low pass filter 134 to remove images caused by digital-to-analog conversion, amplified by a VGA 136, and upconverted from baseband to radio frequency (RF) by a mixer 138. The upconverted signal is filtered by a filter 140, further amplified by a driver amplifier 142 and a power amplifier 144, routed through switches/duplexers 146, and transmitted via an antenna 148.

In the receive path, the antenna 148 receives signals from base stations and/or other transmitter stations and provides a received signal, which is routed through the switches/duplexers 146 and provided to the receiver 150. Within the receiver 150, the received signal is amplified by a low noise amplifier (LNA) 152, filtered by a bandpass filter 154, and downconverted from RF to baseband by a mixer 156. The downconverted signal is amplified by a VGA 158, filtered by a low pass filter 160, and amplified by an amplifier 162 to obtain an analog input signal, which is provided to the data processor 110.

FIG. 1 shows the transmitter 130 and the receiver 150 implementing a direct-conversion architecture, which frequency converts a signal between RF and baseband in one stage. The transmitter 130 and/or the receiver 150 may also implement a super-heterodyne architecture, which frequency converts a signal between RF and baseband in multiple stages. A local oscillator (LO) generator 170 generates and provides transmit and receive LO signals to the mixers 138 and 156, respectively. A phase locked loop (PLL) 172 receives control information from the data processor 110 and provides control signals to the LO generator 170 to generate the transmit and receive LO signals at the proper frequencies.

FIG. 1 shows an exemplary transceiver design. In general, the conditioning of the signals in the transmitter 130 and the receiver 150 may be performed by one or more stages of amplifier, filter, mixer, etc. These circuits may be arranged differently from the configuration shown in FIG. 1. Furthermore, other circuits not shown in FIG. 1 may also be used in the transmitter and the receiver. For example, matching circuits may be used to match various active circuits in FIG. 1. Some circuits in FIG. 1 may also be omitted. The transceiver 120 may be implemented on one or more analog integrated circuits (ICs), radio frequency ICs (RFICs), mixed-signal ICs, etc. For example, the amplifier 132 through the power amplifier 144 in the transmitter 130 may be implemented on an RFIC. The driver amplifier 142 and the power amplifier 144 may also be implemented on another IC external to the RFIC.

The data processor 110 may perform various functions for the wireless communication device 100, e.g., processing for transmitted and received data. A memory 112 may store program codes and data for the data processor 110. The data processor 110 may be implemented on one or more application specific integrated circuits (ASICs) and/or other ICs.

As shown in FIG. 1, a transmitter and a receiver may include various amplifiers. Each amplifier at RF may have input impedance matching and output impedance matching, which are not shown in FIG. 1 for simplicity.

Capacitors are widely used in integrated circuits (e.g., analog integrated circuits). For example, the design of the transmitter and the receiver likely includes differential circuits integrating metal-oxide-metal (MOM)/metal-insulator-metal (MIM)/metal-oxide-semiconductor (MOS) capacitors for alternating current coupling.

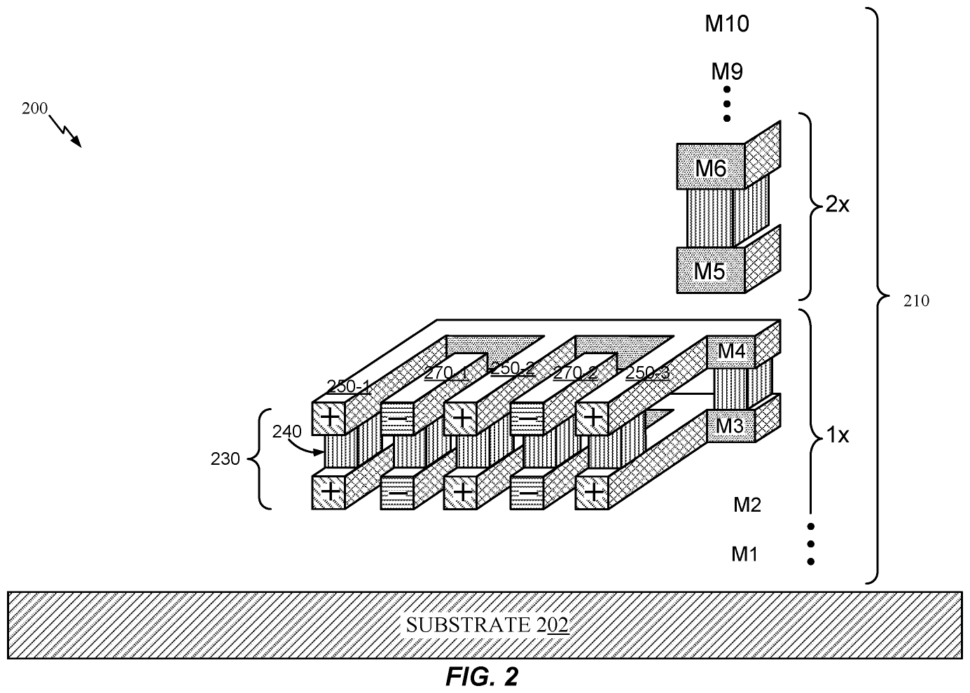

FIG. 2 is a block diagram illustrating a cross-section of an analog integrated circuit (IC) device 200 including an interconnect stack 210. The interconnect stack 210 of the IC device 200 includes multiple conductive interconnect layers (M1, . . . , M9, M10) on a semiconductor substrate (e.g., a diced silicon wafer) 202. The semiconductor substrate 202 support a metal-oxide-metal (MOM) capacitor 230 and/or a metal-oxide-semiconductor (MOS). In this example, the MOM capacitor 230 is formed in the M3 and M4 interconnect layers, below the M5 and M6 interconnect layers. The MOM capacitor 230 is formed from lateral conductive fingers of different polarities using the conductive interconnect layers (M3 and M4) of the interconnect stack 210. A dielectric (not shown) is provided between the conductive fingers.

In this example, the MOM capacitor 230 is formed within the lower conductive interconnect layers (e.g., M1-M4) of the interconnect stack 210. The lower conductive interconnect layers of the interconnect stack 210 have smaller interconnect widths and spaces. For example, the dimensions of the conductive interconnect layers M3 and M4 are half the size of the dimensions of the conductive interconnect layers M5 and M6. Likewise, the dimensions of the conductive interconnect layers M1 and M2 are half the size of the dimensions of the conductive interconnect layers M3 and M4. The small interconnect widths and spaces of the lower conductive interconnect layers enable the formation of MOM capacitors with increased capacitance density.

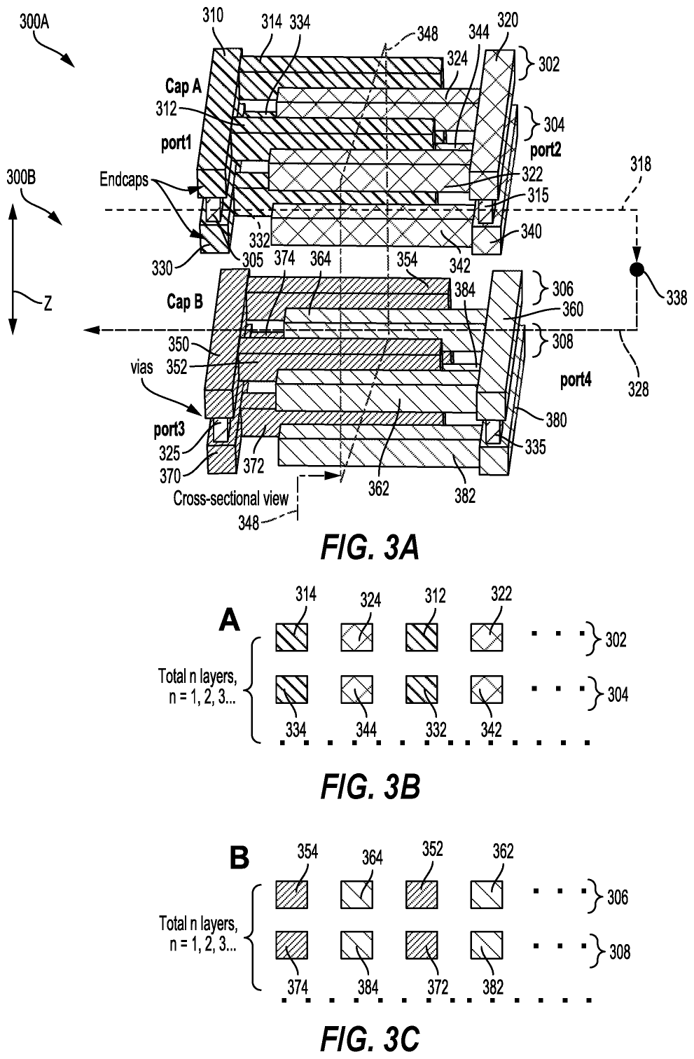

As shown in FIG. 2, the MOM capacitor 230 makes use of a lateral (intra layer) capacitive coupling 240 between fingers (e.g., 250, 270) formed by standard metallization of the conductive interconnects (e.g., wiring lines and vias). The lateral coupling 240 within the MOM capacitor 230 provides improved matching characteristics when compared to the vertical coupling of parallel vertical plate capacitors. The improved matching characteristics of the MOM capacitor 230 are the result of improved process control of the lateral dimensions within the interconnect stack 210. By contrast, the process controls of the vertical dimensions of the conductive interconnect and dielectric layer thickness within the interconnect stack 210 are less precise for fabricating parallel plate capacitors. In aspects of the present disclosure, the multi-layer capacitors are in different paths of a differential circuit and in different interconnect layers, as shown in FIG. 3.

FIG. 3A is a schematic diagram illustrating a differential circuit including metal-oxide-metal capacitors in different paths of the differential circuit and in different interconnect layers, according to aspects of the present disclosure. FIG. 3A includes a first MOM capacitor 300A in a first interconnect layer 302 and a second interconnect layer 304. FIG. 3A also includes a second MOM capacitor 300B in a third interconnect layer 306 and a fourth interconnect layer 308. The first MOM capacitor 300A is in a first path 318 of the differential circuit and the second MOM capacitor 300B is in a second path 328 of the differential circuit. The first path 318 and the second path 328 are coupled to a reference node 338. The reference node 338 may be a terminal of a load (not shown). The first MOM capacitor 300A overlaps at least a portion of the second MOM capacitor 300B.

The first MOM capacitor 300A includes a first capacitor routing terminal (e.g., endcap or manifold) 310 and a second endcap 320 in the first interconnect layer 302. The first endcap 310 is parallel to the second endcap 320. The first endcap 310 is of a first polarity (e.g., positive) and the second endcap 320 is of a second polarity (e.g., negative). A first set of parallel conductive capacitor routing traces (e.g., conductive fingers) of the first MOM capacitor 300A includes a first conductive finger 312 and a second conductive finger 314.

Each of the first conductive finger 312 and the second conductive finger 314 are orthogonally coupled to the first endcap 310. Each of the first conductive finger 312 and the second conductive finger 314 is of the first polarity. A second set of conductive fingers of the first MOM capacitor 300A includes a third conductive finger 322 and a fourth conductive finger 324. Each of the third conductive finger 322 and the fourth conductive finger 324 are orthogonally coupled to the second endcap 320. Each of the third conductive finger 322 and the fourth conductive finger 324 is of the second polarity.

The first set of parallel conductive fingers is interdigitated with the second set of parallel conductive fingers in the first interconnect layer 302. For example, the first conductive finger 312 and the second conductive finger 314 of the first interconnect layer 302 are interdigitated with the third conductive finger 322 and the fourth conductive finger 324 of the first interconnect layer 302.

The second MOM capacitor 300B includes a third capacitor routing terminal (e.g., endcap or manifold) 350 and a fourth endcap 360 in the third interconnect layer 306. The third endcap 350 is parallel to the fourth endcap 360. The third endcap 350 is of the second polarity and the fourth endcap 360 is of the first polarity. A third set of conductive fingers of the second MOM capacitor 300B includes a fifth conductive finger 352 and a sixth conductive finger 354. Each of the fifth conductive finger 352 and the sixth conductive finger 354 are orthogonally coupled to the third endcap 350 of the third interconnect layer 306. Each of the fifth conductive finger 352 and the sixth conductive finger 354 of the third interconnect layer 306 is of the second polarity.

A fourth set of parallel conductive fingers of the second MOM capacitor 300B includes a seventh conductive finger 362 and an eighth conductive finger 364. Each of the seventh conductive finger 362 and the eighth conductive finger 364 is orthogonally coupled to the fourth endcap 360 of the third interconnect layer 306. Each of the seventh conductive finger 362 and the eighth conductive finger 364 is of the first polarity.

The fourth set of parallel conductive fingers is interdigitated with the third set of conductive fingers in the third interconnect layer 306. For example, the fifth conductive finger 352 and the sixth conductive finger 354 of the third interconnect layer 306 are interdigitated with the seventh conductive finger 362 and the eighth conductive finger 364 of the third interconnect layer 306.

The second interconnect layer 304 of the first MOM capacitor 300A also includes endcaps and conductive fingers. For example, the first MOM capacitor 300A includes a fifth endcap 330 and a sixth endcap 340 in the second interconnect layer 304. The fifth endcap 330 is parallel to the sixth endcap 340. The fifth endcap 330 is of the first polarity and the sixth endcap 340 is of the second polarity. A fifth set of parallel conductive fingers of the first MOM capacitor 300A includes a ninth conductive finger 332 and a tenth conductive finger 334.

Each of the ninth conductive finger 332 and the tenth conductive finger 334 is orthogonally coupled to the fifth endcap 330 of the second interconnect layer 304. Each of the ninth conductive finger 332 and the tenth conductive finger 334 is of the first polarity. A sixth set of conductive fingers of the first MOM capacitor 300A includes an eleventh conductive finger 342 and a twelfth conductive finger 344. Each of the eleventh conductive finger 342 and the twelfth conductive finger 344 is orthogonally coupled to the sixth endcap 340 of the second interconnect layer 304. Each of the eleventh conductive finger 342 and a twelfth conductive finger 344 is of the second polarity.

The fifth set of parallel conductive fingers are interdigitated with the sixth set of conductive fingers in the second interconnect layer 304. For example, the ninth conductive finger 332 and the tenth conductive finger 334 are interdigitated with the eleventh conductive finger 342 and the twelfth conductive finger 344 of the second interconnect layer 304.

The fourth interconnect layer 308 of the second MOM capacitor 300B also includes endcaps and conductive fingers. For example, the second MOM capacitor 300B includes a seventh endcap 370 and an eighth endcap 380 in the fourth interconnect layer 308. The seventh endcap 370 is parallel to the eighth endcap 380 of the fourth interconnect layer 308. The seventh endcap 370 is of the second polarity and the eighth endcap 380 is of the first polarity. A seventh set of conductive fingers of the second MOM capacitor 300B includes a thirteenth conductive finger 372 and a fourteenth conductive finger 374. Each of the thirteenth conductive finger 372 and the fourteenth conductive finger 374 is orthogonally coupled to the seventh endcap 370. Each of the thirteenth conductive finger 372 and the fourteenth conductive finger 374 is of the second polarity.

An eighth set of parallel conductive fingers of the second MOM capacitor 300B includes a fifteenth conductive finger 382 and a sixteenth conductive finger 384. Each of the fifteenth conductive finger 382 and the sixteenth conductive finger 384 is orthogonally coupled to the eighth endcap 380 of the fourth interconnect layer 308. Each of the fifteenth conductive finger 382 and the sixteenth conductive finger 384 is of the first polarity.

The seventh set of conductive fingers is interdigitated with the eighth set of parallel conductive fingers in the fourth interconnect layer 308. For example, the thirteenth conductive finger 372 and the fourteenth conductive finger 374 are interdigitated with the fifteenth conductive finger 382 and the sixteenth conductive finger 384.

A first set of vias in the first MOM capacitor 300A is configured to couple one or more endcaps in the first interconnect layer 302 to one or more endcaps in the second interconnect layer 304. For example, a first via 305 couples the first endcap 310 in the first interconnect layer 302 to the fifth endcap 330 in the second interconnect layer 304. Similarly, a second via 315 couples the second endcap 320 in the first interconnect layer 302 to the sixth endcap 340 in the second interconnect layer 304.

A second set of vias in the second MOM capacitor 300B is configured to couple one or more endcaps in the third interconnect layer 306 to one or more endcaps in the fourth interconnect layer 308. For example, a third via 325 couples the third endcap 350 in the third interconnect layer 306 to the seventh endcap 370 in the fourth interconnect layer 308. Similarly, a fourth via 335 couples the fourth endcap 360 in the third interconnect layer 306 to the eighth endcap 380 in the fourth interconnect layer 308.

For example, the first MOM capacitor 300A is an alternating current (AC) coupling capacitor in the first path 318 of the differential circuit and the second MOM capacitor 300B is an AC coupling capacitor in the second path 328 of the differential circuit. The first MOM capacitor 300A includes a first pair of ports (e.g., a first port (port1) and a second port (port2). The first port may have the first polarity and the second port may have the second polarity. The first port of the first MOM capacitor 300A may include the first via 305. In some aspects, at least a portion of the first endcap 310 and the fifth endcap 330 in conjunction with the first via 305 form the first port. The second port of the first MOM capacitor 300A may include the second via 315. In some aspects, at least a portion of the second endcap 320 and the sixth endcap 340 in conjunction with the second via 315 form the second port.

The second MOM capacitor 300B includes a second pair of ports (e.g., a third port (port3) and a fourth port (port4)). The third port is of the second polarity and the fourth port is of the first polarity. Signaling through the differential circuit may flow in a loop from the first port to the second port and from the fourth port to the third port. The third port of the second MOM capacitor 300B may include the third via 325. In some aspects, at least a portion of the third endcap 350 and the seventh endcap 370 in conjunction with the third via 325 form the third port. The fourth port of the second MOM capacitor 300B may include the fourth via 335. In some aspects, at least a portion of the fourth endcap 360 and the eighth endcap 380 in conjunction with the fourth via 335 form the fourth port.

Differential signals (e.g., current) may be communicated to the differential circuit and subsequently communicated to the first MOM capacitor 300A and the second MOM capacitor 300B in the first path 318 and the second path 328 of the differential circuit through the ports. A load configured to receive differential signals may be coupled to the differential circuit at the reference node 338. For example, a first signal of a first polarity may enter the first path 318 of the differential circuit and is provided to the first port (port1) of the first MOM capacitor 300A. The first signal traverses the first MOM capacitor 300A and exits the first MOM capacitor 300A via the second port (port2) and is provided to the load via the reference node 338. Similarly, a second signal of a second polarity may traverse the second path 328 of the differential circuit through the fourth port (port4) and the third port (port3) from the load via the reference node 338.

The overlapped configuration of the first MOM capacitor 300A and the second MOM capacitor 300B in the differential circuit results in improved isolation because of a reduced signal (e.g., current) loop. For example, a center-to-center distance Z between the first MOM capacitor 300A and the second MOM capacitor 300B on different back-end-of-line interconnect layers is smaller (e.g., 0.09 micrometers) relative to a spacing (e.g., thirty micrometers) of a side-by-side configuration. For example, the signal loop includes the first path 318, which includes the first port, the second port, and the reference node 338, as well as the second path 328, which includes the reference node 338, the third port and the fourth port. In one aspect, the center-to-center distance Z between the first MOM capacitor 300A and the second MOM capacitor 300B may be a distance between a center of the first via 305 and a center of the third via 325.

In some aspects, a third set of vias (not shown) may be included in the first MOM capacitor 300A to couple the first set of conductive fingers and/or the second set of conductive fingers in the first interconnect layer 302 to one or more sets of conductive fingers in the second interconnect layer 304. For example, a via of the third set of vias may couple the first conductive finger 312 in the first interconnect layer 302 to the ninth conductive finger 332 in the second interconnect layer 304.

In some aspects, a fourth set of vias (not shown) may be included in the second MOM capacitor 300B to couple the third set of conductive fingers and/or the fourth set of conductive fingers in the third interconnect layer 306 to one or more sets of conductive fingers in the fourth interconnect layer 308. For example, a via of the fourth set of vias may couple the fifth conductive finger 352 in the third interconnect layer 306 to the thirteenth conductive finger 372 in the fourth interconnect layer 308.

FIGS. 3B and 3C illustrate cross-sections of portions of the metal-oxide-metal capacitors of FIG. 3A, according to aspects of the present disclosure. For example, the cross-section may be taken along the region 348.

FIG. 3B is a cross-section of the first interconnect layer 302 and the second interconnect layer 304 of the first MOM capacitor 300A. The first interconnect layer 302 includes the first conductive finger 312, the second conductive finger 314, the third conductive finger 322, and the fourth conductive finger 324 of the first MOM capacitor 300A. The conductive fingers of the first polarity (e.g., the first conductive finger 312 and the second conductive finger 314) of the first interconnect layer 302 are arranged in an alternating configuration with respect to the conductive fingers of the second polarity (e.g., the third conductive finger 322 and the fourth conductive finger 324).

The second interconnect layer 304 includes the ninth conductive finger 332, the tenth conductive finger 334, the eleventh conductive finger 342, and the twelfth conductive finger 344 of the first MOM capacitor 300A. The conductive fingers of the first polarity (e.g., the ninth conductive finger 332 and the tenth conductive finger 334) of the second interconnect layer 304 are arranged in an alternating configuration with respect to the conductive fingers of the second polarity (e.g., the eleventh conductive finger 342 and the twelfth conductive finger 344).

In this configuration, the conductive fingers of the same polarity in the first interconnect layer 302 are aligned with conductive fingers of the same polarity in the second interconnect layer 304. For example, the first conductive finger 312 and the second conductive finger 314 of the first interconnect layer 302, are respectively aligned with (e.g., overlap or directly over/below) the ninth conductive finger 332 and the tenth conductive finger 334 of the second interconnect layer 304. The third conductive finger 322 and the fourth conductive finger 324 of the first interconnect layer 302, are respectively aligned with (e.g., overlap or directly over/below) the eleventh conductive finger 342 and the twelfth conductive finger 344 of the second interconnect layer 304.

FIG. 3C is a cross-section of the third interconnect layer 306 and the fourth interconnect layer 308 of the second MOM capacitor 300B. The third interconnect layer 306 includes the fifth conductive finger 352, the sixth conductive finger 354, the seventh conductive finger 362, and the eighth conductive finger 364 of the second MOM capacitor 300B. The conductive fingers of the second polarity (e.g., the fifth conductive finger 352 and the sixth conductive finger 354) of the third interconnect layer 306 are arranged in an alternating configuration with respect to the conductive fingers of the first polarity (e.g., the seventh conductive finger 362 and the eighth conductive finger 364).

The fourth interconnect layer 308 includes the thirteenth conductive finger 372, the fourteenth conductive finger 374, the fifteenth conductive finger 382, and the sixteenth conductive finger 384 of the second MOM capacitor 300B. The conductive fingers of the second polarity (e.g., the thirteenth conductive finger 372 and the fourteenth conductive finger 374) of the fourth interconnect layer 308 are arranged in an alternating configuration with respect to the conductive fingers of the first polarity (e.g., the fifteenth conductive finger 382 and the sixteenth conductive finger 384).

In this configuration, the conductive fingers of the same polarity in the third interconnect layer 306 are aligned with conductive fingers of the same polarity in the fourth interconnect layer 308. For example, the fifth conductive finger 352 and the sixth conductive finger 354 of the third interconnect layer 306, are respectively aligned with (e.g., overlap or directly over/below) the thirteenth conductive finger 372 and the fourteenth conductive finger 374 of the fourth interconnect layer 308. The seventh conductive finger 362 and the eighth conductive finger 364 of the third interconnect layer 306, are respectively aligned with the fifteenth conductive finger 382 and the sixteenth conductive finger 384 of the fourth interconnect layer 308.

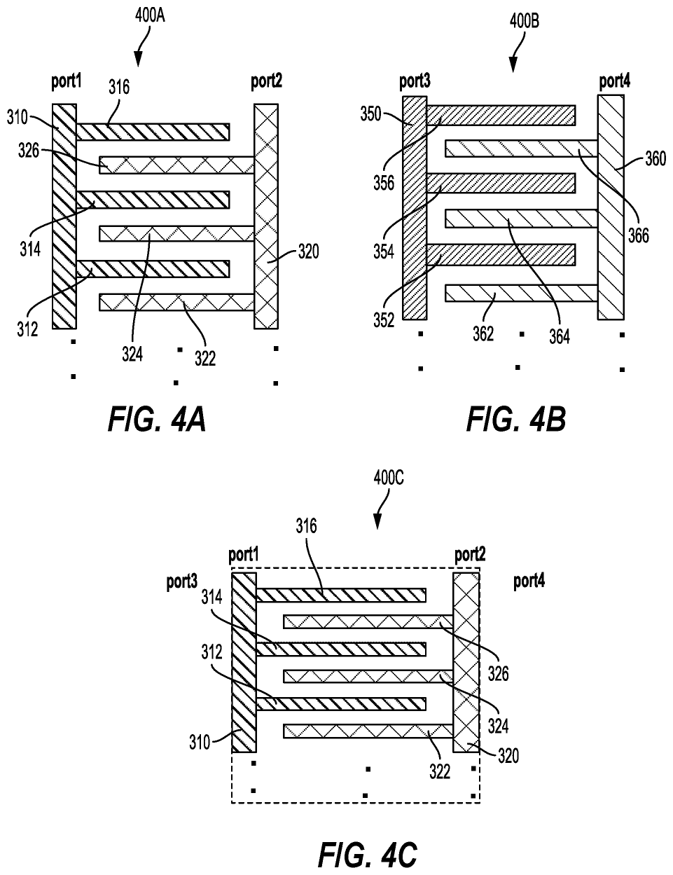

FIG. 4A illustrates a top view of a first metal-oxide-metal (MOM) capacitor 400A used in a first path of a differential circuit, according to aspects of the present disclosure. For illustrative purposes, some or all of the labelling and numbering of the devices and features of FIG. 4A are similar to those of FIGS. 3A and 3B. For example, the top view of the first MOM capacitor 400A is similar to a top view of the first MOM capacitor 300A. However, the top view of the first MOM capacitor 400A includes additional conductive fingers such as a first additional conductive finger 316 of the first polarity and a second additional conductive finger 326 of the second polarity. The first additional conductive finger 316 is orthogonally coupled to the first endcap 310. The second additional conductive finger 326 is orthogonally coupled to the second endcap 320.

FIG. 4B illustrates a top view of a second MOM capacitor 400B used in a second path of the differential circuit, according to aspects of the present disclosure. For illustrative purposes, some or all of the labelling and numbering of the devices and features of FIG. 4B are similar to those of FIGS. 3A and 3C. For example, the top view of a second MOM capacitor 400B is similar to a top view of the second MOM capacitor 300B. However, the top view of the second MOM capacitor 400B includes additional conductive fingers such as a third additional conductive finger 356 of the second polarity and a fourth additional conductive finger 366 of the first polarity. The third additional conductive finger 356 is orthogonally coupled to the third endcap 350. The fourth additional conductive finger 366 is orthogonally coupled to the fourth endcap 360.

FIG. 4C illustrates a top view of a capacitor structure 400C including the first MOM capacitor 400A overlapping the second MOM capacitor 400B, according to aspects of the present disclosure. In some aspects of the present disclosure, the first MOM capacitor 400A has a same dimension as the second MOM capacitor 400B. In this aspect, when the first MOM capacitor 400A in the first interconnect layer 302 and the second interconnect layer 304 directly overlaps (e.g., is directly aligned and over) the second MOM capacitor 400B in the third interconnect layer 306 and the fourth interconnect layer 308, the top view of the capacitor structure 400C only shows the top view of the first MOM capacitor 400A. This follows because the first MOM capacitor 400A completely covers the second MOM capacitor 400B.

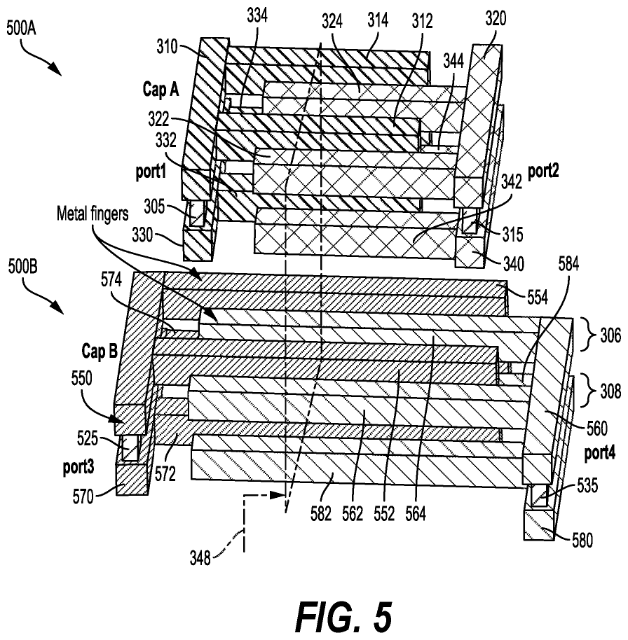

FIG. 5 is a schematic diagram of metal-oxide-metal (MOM) capacitors for different paths of a differential circuit in different interconnect layers, according to aspects of the present disclosure. For illustrative purposes, some or all of the labelling and numbering of the devices and features of FIG. 5 are similar to those of FIGS. 3A-3C.

For example, the MOM capacitors of FIG. 5 include a first MOM capacitor 500A, which is the same as the first MOM capacitor 300A. The MOM capacitors of FIG. 5 also include a second MOM capacitor 500B that is similar to the second MOM capacitor 300B. However, the dimensions of the second MOM capacitor 500B are different from the dimensions of the second MOM capacitor 300B. For example, at least some of the dimensions of the second MOM capacitor 500B are larger than the corresponding dimensions of the second MOM capacitor 300B. While the endcaps, conductive fingers and vias of the second MOM capacitor 500B are numbered starting with five (5) instead of three (3) as with the second MOM capacitor 300B, the different numbering is merely used to indicate that at least some of the features of the second MOM capacitor 500B are larger than those of the second MOM capacitor 300B.

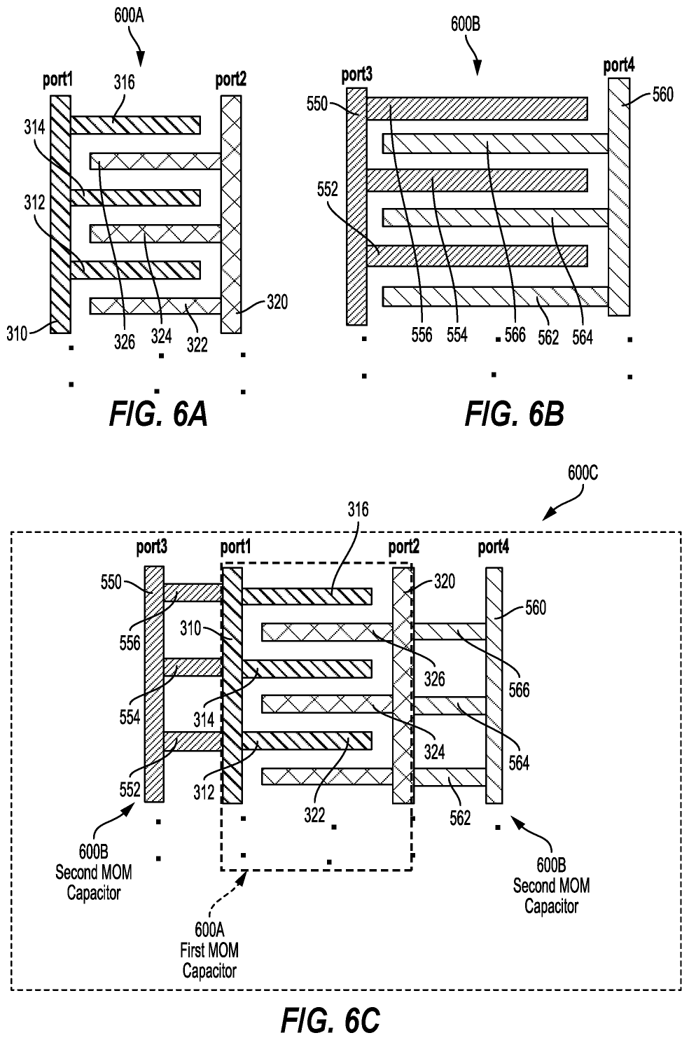

For example, the second MOM capacitor 500B includes a fifth conductive finger 552 and a sixth conductive finger 554 that are similar to the fifth conductive finger 352 and the sixth conductive finger 354 of the second MOM capacitor 300B but longer. While only these fingers are discussed in the interest of brevity, the different dimensions may be applicable to other features such as endcaps, vias, and other conductive fingers. These differences in dimensions are further illustrated in FIGS. 6A-6C.

FIG. 6A illustrates a top view of a first metal-oxide-metal (MOM) capacitor 600A used in a first path of a differential circuit, according to aspects of the present disclosure. For illustrative purposes, some or all of the labelling and numbering of the devices and features of FIG. 6A are similar to those of FIGS. 3A, 3B, and 4A. For example, the top view of the first MOM capacitor 600A is the same as the top view of the first MOM capacitor 400A.

FIG. 6B illustrates a top view of a second MOM capacitor 600B having a different dimension than the first MOM capacitor 600A of FIG. 6A and used in a second path of the differential circuit, according to aspects of the present disclosure. For illustrative purposes, some or all of the labelling and numbering of the devices and features of FIG. 6B are similar to those of FIGS. 3A, 3C, 4B, and 5. For example, the top view of the second MOM capacitor 600B is the same as the top view of the second MOM capacitor 500B of FIG. 5. As noted in the description of FIG. 5, the second MOM capacitor 500B is dimensionally larger than the second MOM capacitor 300B. By extension, the second MOM capacitor 600B is also dimensionally larger than the second MOM capacitor 300B as well as the first MOM capacitor 300A, which has the same dimensions as the second MOM capacitor 300B.

FIG. 6C illustrates a top view of a capacitor structure 600C including the first MOM capacitor 600A of FIG. 6A overlapping a top view of the second MOM capacitor 600B of FIG. 6B, according to aspects of the present disclosure. In this aspect of the present disclosure, the first MOM capacitor 600A is dimensionally smaller than the second MOM capacitor 600B. Thus, when the first MOM capacitor 600A in the first interconnect layer 302 and the second interconnect layer 304 directly overlap (e.g., is directly over and aligned) the second MOM capacitor 600B in the third interconnect layer 306 and the fourth interconnect layer 308, the top view of the capacitor structure 600C shows the top view of the first MOM capacitor 600A and portions of the second MOM capacitor 600B that are not covered by the first MOM capacitor 600A. This follows because the dimensionally smaller first MOM capacitor 600A cannot completely cover the dimensionally larger second MOM capacitor 600B.

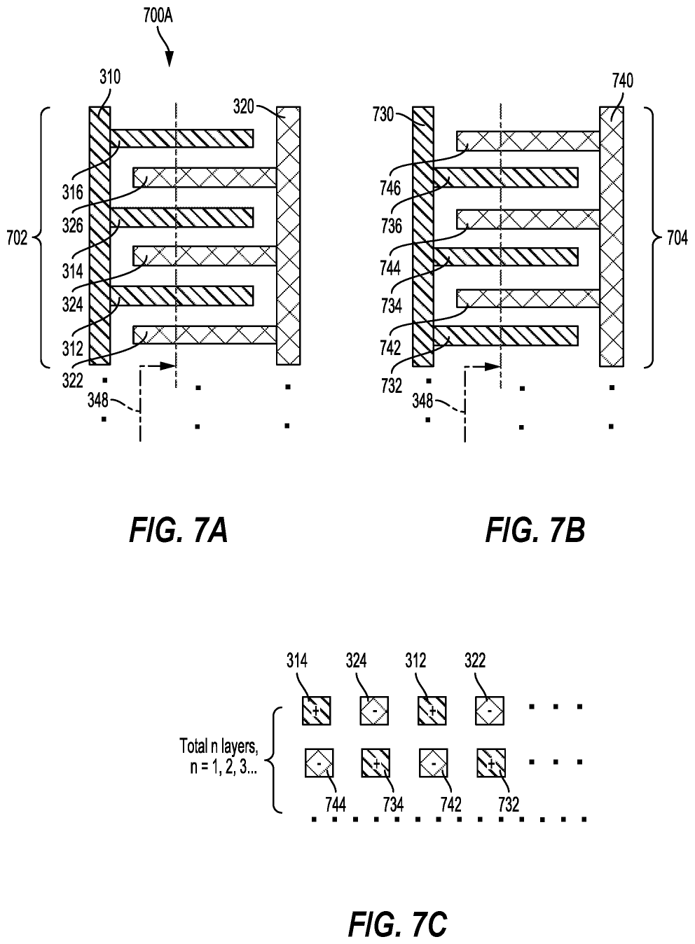

FIG. 7A illustrates a top view of a first interconnect layer 702 of a metal-oxide-metal (MOM) capacitor 700 used in a first path of a differential circuit, according to aspects of the present disclosure. For illustrative purposes, some or all of the labelling and numbering of the devices and features of FIG. 7A are similar to those of FIGS. 3A and 4A. For example, the top view of the first interconnect layer 702 of the MOM capacitor 700 is the same as the top view of the first MOM capacitor 400A of FIG. 4A. Thus, the first interconnect layer 302 of FIG. 3A is the same as the first interconnect layer 702 of FIG. 7A.

FIG. 7B illustrates a top view of a second interconnect layer 704 of the metal-oxide-metal (MOM) capacitor 700 of FIG. 7A, according to aspects of the present disclosure. For illustrative purposes, some or all of the labelling and numbering of the devices and features of FIG. 7B are similar to those of FIG. 3A. For example, the top view of the second interconnect layer 704 of the MOM capacitor 700 is similar to a top view of the second interconnect layer 304 of the first MOM capacitor 300A of FIG. 3A.

Similar to the second interconnect layer 304 of FIG. 3A that includes the fifth endcap 330 and the sixth endcap 340, the second interconnect layer 704 of FIG. 7B includes a ninth endcap 730 and a tenth endcap 740. Also, similar to the second interconnect layer 304 that includes the ninth conductive finger 332 and the tenth conductive finger 334 that are orthogonally coupled to the fifth endcap 330, the second interconnect layer 704 includes a seventeenth conductive finger 732 and an eighteenth conductive finger 734 orthogonally coupled to the ninth endcap 730. In addition, similar to the second interconnect layer 304 that includes the eleventh conductive finger 342 and the twelfth conductive finger 344 that are orthogonally coupled to the sixth endcap 340, the second interconnect layer 704 includes a nineteenth conductive finger 742 and a twentieth conductive finger 744 orthogonally coupled to the tenth endcap 740.

However, unlike the top view of the second interconnect layer 304, the top view of the second interconnect layer 704 includes additional conductive fingers such as a first additional conductive finger 736 of the first polarity and a second additional conductive finger 746 of the second polarity. The first additional conductive finger 736 is orthogonally coupled to the ninth endcap 730. The second additional conductive finger 746 is orthogonally coupled to the tenth endcap 740. Furthermore, the conductive fingers of the second interconnect layer 704 are arranged such that the conductive fingers of the same polarity in the first interconnect layer 702 of FIG. 7A are not aligned with conductive fingers of the same polarity in the second interconnect layer 704 of FIG. 7B, as illustrated in FIG. 7C.

FIG. 7C illustrates a cross-section of the metal-oxide-metal (MOM) capacitor 700 of FIG. 7A. The cross-section may be taken along the region 348 as illustrated in the first interconnect layer 702 of FIG. 7A and the second interconnect layer 704 of FIG. 7B. The conductive fingers of the first polarity (e.g., the first conductive finger 312 and the second conductive finger 314) of the first interconnect layer 702 are arranged in an alternating configuration with respect to the conductive fingers of the second polarity (e.g., the third conductive finger 322 and the fourth conductive finger 324). The conductive fingers of the first polarity (e.g., the seventeenth conductive finger 732 and the eighteenth conductive finger 734) of the second interconnect layer 704 are also arranged in an alternating configuration with respect to the conductive fingers of the second polarity (e.g., the nineteenth conductive finger 742 and the twentieth conductive finger 744).

In this configuration, the conductive fingers of the same polarity in the first interconnect layer 702 are not aligned with conductive fingers of the same polarity in the second interconnect layer 704. For example, the conductive fingers of the first polarity including the first conductive finger 312 and the second conductive finger 314 of the first interconnect layer 702, are respectively aligned with (e.g., overlap or directly over/below) the conductive fingers of the second polarity including the nineteenth conductive finger 742 and the twentieth conductive finger 744 of the second interconnect layer 704. Similarly, the conductive fingers of the second polarity including the third conductive finger 322 and the fourth conductive finger 324 of the first interconnect layer 702, are respectively aligned with (e.g., overlap or directly over/below) the conductive fingers of the first polarity including the seventeenth conductive finger 732 and the eighteenth conductive finger 734 of the second interconnect layer 704.

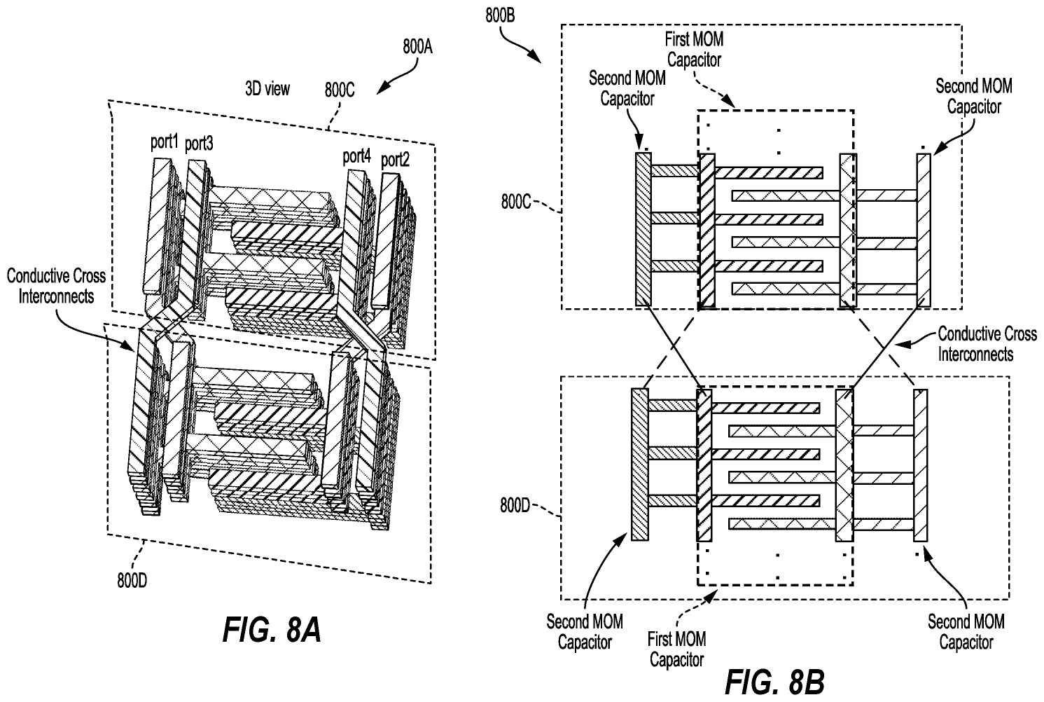

FIG. 8A illustrates a three-dimensional view of a dual capacitor structure 800A and FIG. 8B illustrates a top view 800B of the dual capacitor structure 800A, according to aspects of the present disclosure. The dual capacitor structure 800A includes a first capacitor structure 800C and a second capacitor structure 800D. Each of the first capacitor structure 800C and the second capacitor structure 800D are similar to the capacitor structure 600C of FIG. 6C. In this configuration, the first capacitor structure 800C and the second capacitor structure 800D are in a side-by-side configuration and are included in a first path (e.g., the first path 318 shown in FIG. 3A) and a second path (e.g., the second path 328 shown in FIG. 3A) of the differential circuit.

For example, the first MOM capacitor of the first capacitor structure 800C and the first MOM capacitor of the second capacitor structure 800D may be in the first path. The second MOM capacitor of the first capacitor structure 800C and the second MOM capacitor of the second capacitor structure 800D may be in the second path. The MOM capacitors of the first capacitor structure 800C and the second capacitor structure 800D may be coupled together using conductive (e.g., metal) cross interconnects in different back-end-of-line interconnect layers.

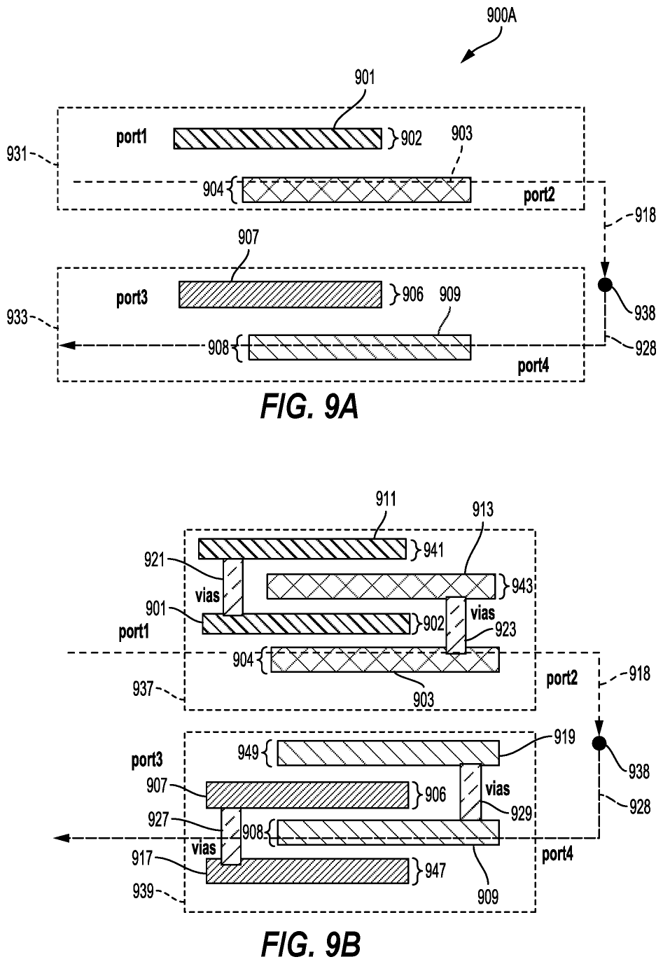

FIG. 9A is a schematic diagram illustrating an integrated circuit (e.g., a differential circuit) 900A including metal-insulator-metal (MIM) capacitors in different paths of the differential circuit and in different interconnect layers, according to aspects of the present disclosure. The MIM capacitors include a first MIM capacitor 931 and a second MIM capacitor 933. The first MIM capacitor 931 includes a first conductive plate 901 in a first interconnect layer 902 and a second conductive plate 903 in a second interconnect layer 904. A dielectric material is between the first conductive plate 901 and the second conductive plate 903. Similar to the first MOM capacitor 300A, which overlaps at least a portion of the second MOM capacitor 300B, the first MIM capacitor 931 overlaps at least a portion of the second MIM capacitor 933.

The second MIM capacitor 933 includes a third conductive plate 907 in a third interconnect layer 906 and a fourth conductive plate 909 in a fourth interconnect layer 908. A dielectric material is between the third conductive plate 907 and the fourth conductive plate 909. The dielectric material may be configured to reduce any direct current (DC) leakage current through the first MIM capacitor 931 and through the second MIM capacitor 933. Accordingly, the MIM capacitors may be implemented as AC coupling capacitors in the differential circuit.

The first MIM capacitor 931 is included in a first path 918 of the differential circuit and the second MIM capacitor 933 is included in a second path 928 of the differential circuit. A load configured to receive differential signals may be coupled to the differential circuit at a reference node 938. For example, the first path 918 and the second path 928 share the reference node 938 that is coupled to a load (not shown). The first path 918 is similar to the first path 318, the second path 928 is similar to the second path 328, and the reference node 938 is similar to the reference node 338. The first MIM capacitor 931 includes a first pair of ports (e.g., port1 and port2) and the second MIM capacitor 933 includes a second pair of ports (e.g., port3 and port4). In one aspect, the first port and the fourth port are of the first polarity and the second port and the third port are of the second polarity. Signaling through the differential circuit may flow in a loop from the first port, to the second port and from the fourth port to the third port.

A first signal of a first polarity may traverse the first path 918 of the differential circuit through a first port (e.g., port1) and a second port (e.g., port2) to the load via the reference node 938. For example, the first signal enters the first path 918 of the differential circuit and is provided to the first port (port1) of the first MIM capacitor 931. The first port is on the first conductive plate 901. The first signal traverses the first MIM capacitor 931 and exits the first MIM capacitor 931 via the second port (port2) and is provided to the load via the reference node 938. The second port is on the second conductive plate 903.

Similarly, a second signal of a different polarity may traverse the second path 928 of the differential circuit through a third port (port3) and a fourth port (port4) from the load via the reference node 938. The third port is on the third conductive plate 907 and the fourth port is on the fourth conductive plate 909.

FIG. 9B is a schematic diagram illustrating a differential circuit including metal-insulator-metal (MIM) capacitors in different paths of the differential circuit and in different interconnect layers, according to aspects of the present disclosure. For illustrative purposes, some or all of the labelling and numbering of the devices and features of FIG. 9B are similar to those of FIG. 9A. However, in addition to the first conductive plate 901, the second conductive plate 903, the third conductive plate 907, and the fourth conductive plate 909, the metal-insulator-metal capacitors of FIG. 9B include a fifth conductive plate 911, a sixth conductive plate 913, a seventh conductive plate 917, an eighth conductive plate 919, a fifth via 921, a sixth via 923, a seventh via 927, and an eighth via 929.

A third MIM capacitor 937 of FIG. 9B includes the first conductive plate 901, the second conductive plate 903, the fifth conductive plate 911, the sixth conductive plate 913, the fifth via 921, and the sixth via 923. A fourth MIM capacitor 939 of FIG. 9B includes the third conductive plate 907, the fourth conductive plate 909, the seventh conductive plate 917, the eighth conductive plate 919, the seventh via 927, and the eighth via 929. Similar to the first MOM capacitor 300A, which overlaps at least a portion of the second MOM capacitor 300B, the third MIM capacitor 937 overlaps at least a portion of the fourth MIM capacitor 939. This overlap may also be a direct overlap as discussed.

The first port (port1) of a first pair of ports of FIG. 9B includes a first pair of plates (e.g., the first conductive plate 901 and the fifth conductive plate 911) coupled with at least one via (e.g., the fifth via 921) between the first interconnect layer 902 and a first additional interconnect layer 941. The second port (port2) of the first pair of ports of FIG. 9B includes a second pair of plates (e.g., the second conductive plate 903 and the sixth conductive plate 913) coupled with at least one via (e.g., the sixth via 923) between the second interconnect layer 904 and a second additional interconnect layer 943.

The third port (port3) of a second pair of ports of FIG. 9B includes a third pair of plates (e.g., the third conductive plate 907 and the seventh conductive plate 917) coupled with at least one via (e.g., the seventh via 927) between the third interconnect layer 906 and a third additional interconnect layer 947. The fourth port (port4) of the second pair of ports of FIG. 9B includes a fourth pair of plates (e.g., the fourth conductive plate 909 and the eighth conductive plate 919) coupled with at least one via (e.g., the eighth via 929) between the fourth interconnect layer 908 and a fourth additional interconnect layer 949. In some aspects, the first conductive plate 901 and the fifth conductive plate 911 are interdigitated with the second conductive plate 903 and the sixth conductive plate 913. Similarly, the third conductive plate 907 and the seventh conductive plate 917 are interdigitated with the fourth conductive plate 909 and the eighth conductive plate 919.

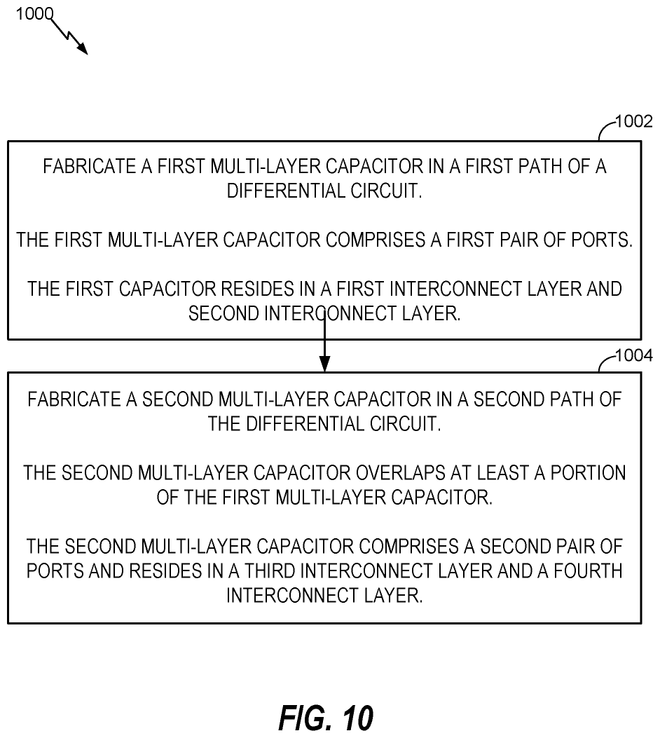

FIG. 10 is a process flow diagram illustrating a method 1000 for fabricating an integrated circuit, according to an aspect of the present disclosure. In block 1002, a first multi-layer capacitor in a first path of a differential circuit is fabricated. The first multi-layer capacitor includes a first pair of ports. The first multi-layer capacitor resides in a first interconnect layer and a second interconnect layer. In block 1004, a second multi-layer capacitor in a second path of the differential circuit is fabricated. The second multi-layer capacitor overlaps one or more portions of the first multi-layer capacitor. The second multi-layer capacitor includes a second pair of ports and resides in third and fourth interconnect layers.

According to a further aspect of the present disclosure, a stacked capacitor is described. In one configuration, the stacked capacitor includes means for harnessing charge between plates formed by metallization layers and wiring traces. The charge harnessing means, for example, includes the first MOM capacitor 400A, first MOM capacitor 500A, the first MOM capacitor 600A, the first MIM capacitor 931 and/or the third MIM capacitor 937. In another aspect, the aforementioned means may be any structure or any material configured to perform the functions recited by the aforementioned means.

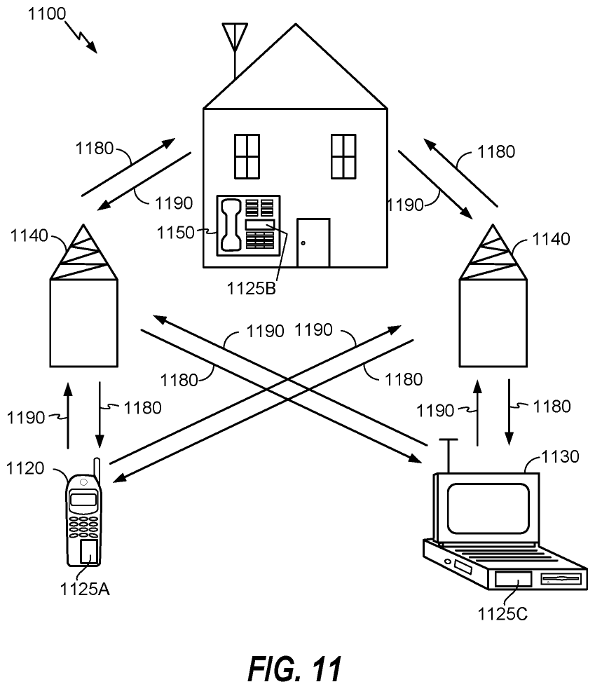

FIG. 11 is a block diagram showing an exemplary wireless communication system 1100 in which an aspect of the present disclosure may be advantageously employed. For purposes of illustration, FIG. 11 shows three remote units 1120, 1130, and 1150 and two base stations 1140. It will be recognized that wireless communication systems may have many more remote units and base stations. Remote units 1120, 1130, and 1150 include IC devices 1125A, 1125C, and 1125B that include the disclosed capacitor. It will be recognized that other devices may also include the disclosed capacitor, such as the base stations, switching devices, and network equipment. FIG. 11 shows forward link signals 1180 from the base station 1140 to the remote units 1120, 1130, and 1150 and reverse link signals 1190 from the remote units 1120, 1130, and 1150 to base stations 1140.

In FIG. 11, remote unit 1120 is shown as a mobile telephone, remote unit 1130 is shown as a portable computer, and remote unit 1150 is shown as a fixed location remote unit in a wireless local loop system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a fixed location data unit, such as a meter reading equipment, or other device that stores or retrieves data or computer instructions, or combinations thereof. Although FIG. 11 illustrates remote units, according to the aspects of the present disclosure, the present disclosure is not limited to these exemplary illustrated units. Aspects of the present disclosure may be suitably employed in many devices, which include the disclosed capacitor.

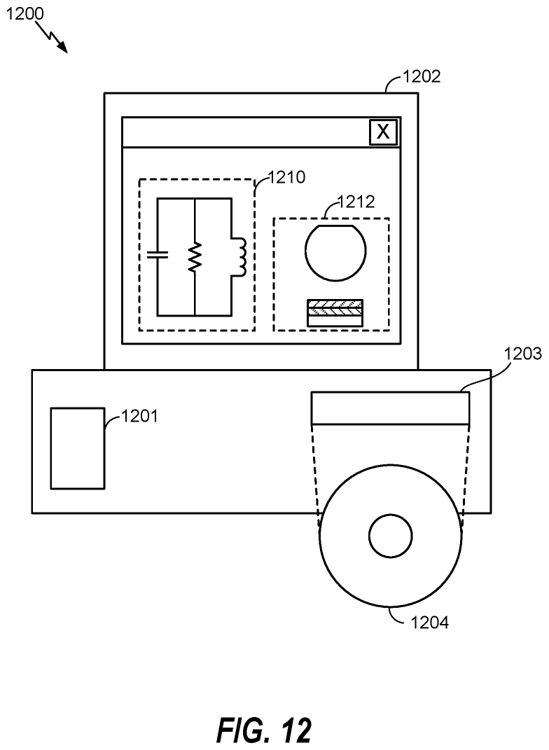

FIG. 12 is a block diagram illustrating a design workstation used for circuit, layout, and logic design of a semiconductor component, such as the capacitors disclosed above. A design workstation 1200 includes a hard disk 1201 containing operating system software, support files, and design software such as Cadence or OrCAD. The design workstation 1200 also includes a display 1202 to facilitate design of a circuit 1210 or an RF component 1212 such as the capacitor. A storage medium 1204 is provided for tangibly storing the design of the circuit 1210 or the RF component 1212 (e.g., the capacitor). The design of the circuit 1210 or the RF component 1212 may be stored on the storage medium 1204 in a file format such as GDSII or GERBER. The storage medium 1204 may be a CD-ROM, DVD, hard disk, flash memory, or other appropriate device. Furthermore, the design workstation 1200 includes a drive apparatus 1203 for accepting input from or writing output to the storage medium 1204.

Data recorded on the storage medium 1204 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1204 facilitates the design of the circuit 1210 or the RF component 1212 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the present disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods, and steps described in the specification. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding configurations described herein may be utilized, according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the present disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. In addition, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media.

The previous description of the present disclosure is provided to enable any person skilled in the art to make or use the present disclosure. Various modifications to the present disclosure will be readily apparent to those skilled in the art, and the generic principles defined herein may be applied to other variations without departing from the spirit or scope of the present disclosure. Thus, the present disclosure is not intended to be limited to the examples and designs described herein but is to be accorded the widest scope consistent with the principles and novel features disclosed herein.

1. An integrated circuit, comprising:
a first multi-layer capacitor in a first path of a differential circuit, the first multi-layer capacitor comprising a first pair of ports, the first multi-layer capacitor residing in a first interconnect layer and a second interconnect layer, wherein the first pair of ports comprises a first port and a second port, a first portion of the first port and a first portion of the second port are in the first interconnect layer, and a second portion of the first port and a second portion of the second port are in the second interconnect layer; and
a second multi-layer capacitor in a second path of the differential circuit, the second multi-layer capacitor overlapping at least a portion of the first multi-layer capacitor, the second multi-layer capacitor comprising a second pair of ports and residing in a third interconnect layer and a fourth interconnect layer, the first multi-layer capacitor physically separated from the second multi-layer capacitor.

2. The integrated circuit of claim 1, in which the first multi-layer capacitor comprises:
a first endcap comprising the first portion of the first port;
a second endcap parallel to the first endcap and comprising the first portion of the second port;
a first set of conductive fingers orthogonally coupled to the first endcap; and
a second set of conductive fingers orthogonally coupled to the second endcap, the second set of conductive fingers interdigitated with the first set of conductive fingers in the first interconnect layer.

3. The integrated circuit of claim 2, further comprising:
a set of vias configured to couple the first set of conductive fingers and/or the second set of conductive fingers in the first interconnect layer to at least one set of conductive fingers in the second interconnect layer.

4. (canceled)

5. The integrated circuit of claim 2, in which the second multi-layer capacitor comprises:
a third endcap comprising a first portion of a third port of the second pair of ports;
a fourth endcap parallel to the third endcap and comprising a first portion of a fourth port of the second pair of ports;
a third set of conductive fingers orthogonally coupled to the third endcap; and
a fourth set of conductive fingers orthogonally coupled to the fourth endcap, the third set of conductive fingers interdigitated with the fourth set of conductive fingers in the third interconnect layer.

6. The integrated circuit of claim 1, in which the first multi-layer capacitor has a same dimension as the second multi-layer capacitor.

7. The integrated circuit of claim 1, in which the first multi-layer capacitor has a different dimension than the second multi-layer capacitor.

8. The integrated circuit of claim 1, in which the first multi-layer capacitor comprises a first metal insulator metal (MIM) capacitor, comprising:
a first plate in the first interconnect layer; and
a second plate in the second interconnect layer; and
in which the second multi-layer capacitor comprises a second metal insulator metal (MIM) capacitor, comprising:
a third plate in the third interconnect layer; and
a fourth plate in the fourth interconnect layer.

9. The integrated circuit of claim 1, in which the first port of the first pair of ports comprises a first pair of plates coupled with at least one via in the first interconnect layer and the third interconnect layer and in which the second port of the first pair of ports comprises a second pair of plates coupled with at least one via in the second interconnect layer and the fourth interconnect layer.

10. A method of fabricating an integrated circuit comprising;
fabricating a first multi-layer capacitor in a first path of a differential circuit, the first multi-layer capacitor comprising a first pair of ports, the first multi-layer capacitor residing in a first interconnect layer and a second interconnect layer, wherein the first pair of ports comprises a first port and a second port, a first portion of the first port and a first portion of the second port are in the first interconnect layer, and a second portion of the first port and a second portion of the second port are in the second interconnect layer; and
fabricating a second multi-layer capacitor in a second path of the differential circuit, the second multi-layer capacitor overlapping at least a portion of the first multi-layer capacitor, the second multi-layer capacitor comprising a second pair of ports and residing in a third interconnect layer and a fourth interconnect layer, the first multi-layer capacitor physically separated from the second multi-layer capacitor.

11. The method of claim 10, in which fabricating the first multi-layer capacitor comprises:
fabricating a first endcap comprising the first portion of the first port;
fabricating a second endcap parallel to the first endcap and comprising the first portion of the second port;
fabricating a first set of conductive fingers orthogonally coupled to the first endcap; and
fabricating a second set of conductive fingers orthogonally coupled to the second endcap, the second set of conductive fingers interdigitated with the first set of conductive fingers in the first interconnect layer.

12. The method of claim 11, further comprising:
fabricating a set of vias configured to couple the first set of conductive fingers and/or the second set of conductive fingers in the first interconnect layer to at least one set of conductive fingers in the second interconnect layer.

13. (canceled)

14. A radio frequency front end module, comprising:
an integrated circuit having a first multi-layer capacitor in a first path of a differential circuit, the first multi-layer capacitor comprising a first pair of ports, the first multi-layer capacitor residing in a first interconnect layer and a second interconnect layer, wherein the first pair of ports comprises a first port and a second port, a first portion of the first port and a first portion of the second port are in the first interconnect layer, and a second portion of the first port and a second portion of the second port are in the second interconnect layer; and a second multi-layer capacitor in a second path of the differential circuit, the second multi-layer capacitor overlapping at least a portion of the first multi-layer capacitor, the second multi-layer capacitor comprising a second pair of ports and residing in a third interconnect layer and a fourth interconnect layer, the first multi-layer capacitor physically separated from the second multi-layer capacitor; and
an antenna coupled to the integrated circuit.

15. The radio frequency front end module of claim 14, in which the first multi-layer capacitor comprises:
a first endcap comprising the first portion of the first port;
a second endcap parallel to the first endcap and comprising the first portion of the second port;
a first set of conductive fingers orthogonally coupled to the first endcap; and
a second set of conductive fingers orthogonally coupled to the second endcap, the second set of conductive fingers interdigitated with the first set of conductive fingers in the first interconnect layer.

16. The radio frequency front end module of claim 15, further comprising:
a set of vias configured to couple the first set of conductive fingers and/or the second set of conductive fingers in the first interconnect layer to at least one set of conductive fingers in the second interconnect layer.

17. (canceled)

18. The radio frequency front end module of claim 15, in which the second multi-layer capacitor comprises:
a third endcap comprising a first portion of a third port of the second pair of ports; a fourth endcap parallel to the third endcap and comprising a first portion of a fourth port of the second pair of ports;
a third set of conductive fingers orthogonally coupled to the third endcap; and
a fourth set of conductive fingers orthogonally coupled to the fourth endcap, the third set of conductive fingers interdigitated with the fourth set of conductive fingers in the third interconnect layer.

19. The radio frequency front end module of claim 14, in which the first multi-layer capacitor has a same dimension as the second multi-layer capacitor.

20. The radio frequency front end module of claim 14, in which the first multi-layer capacitor has a different dimension than the second multi-layer capacitor.
